(19) United States
(12) Patent Application Publication
(10) Pub. No.: US 2022/0285150 A1
(43) Pub. Date: Sep. 8, 2022

(54) METHOD FOR FORMING CONTACT SURFACE ON TOP OF MESA STRUCTURE FORMED ON SEMICONDUCTOR SUBSTRATE

(71) Applicant: Modulight Oy, Tampere (FI)

(72) Inventors: Riina Ulkuniemi, Tampere (FI); Ville Vilokkinen, Tampere (FI); Petri Melanen, Tampere (FI)

(73) Assignee: Modulight Oy, Tampere (FI)

(21) Appl. No.: 17/192,233

(22) Filed: Mar. 4, 2021

(51) Int. Cl. H01L 21/02; H01L 21/308; H01L 21/3065; H01S 5/10; H01S 5/22

(52) U.S. Cl. CPC H01L 21/02227; H01L 21/308; H01L 21/3065; H01S 5/1003; H01S 5/22

(57) ABSTRACT

A method for forming a contact surface on a top of a mesa structure formed on a semiconductor substrate deposited with an insulating layer. The method includes depositing a first resist layer over the insulating layer, depositing a second resist layer over the first resist layer, defining a first portion of the second resist layer, wherein the first portion overlaps the top of the mesa structure, forming a first opening in the first portion by treating the second resist layer to expose a second portion of the first resist layer beneath thereof, forming a second opening in the first resist layer, by treating the exposed second portion to expose a third portion of the insulating layer beneath thereof, and etching the exposed third portion to form the contact surface on the top of the mesa structure.

### TECHNICAL FIELD

The present disclosure relates to fabrication of semiconductor devices; and more specifically to a method for forming a contact surface on a top of a mesa structure formed on a semiconductor substrate.

### BACKGROUND

Fabrication methods that are employed to tailor surface properties of semiconductors have become increasingly important as new applications for semiconductor-based materials continue to be developed. Typically, a semiconductor device such as a semiconductor laser is fabricated from semiconductor wafers or substrates, wherein a designated structure is formed via one or more epitaxial methods such as, for example, a metal organic chemical vapor deposition (MOCVD) method. Generally, the formed structure comprises a p/n-junction with active region on top of a substrate wafer. Upon proper fabrication of the semiconductor substrate to laser chips, a current is driven through the pn-junction for lasing or laser formation.

If only current determines where gain is obtained, device is called a gain-guided laser. It is also possible to enhance gain properties by index-guiding, where optical field is confined with refractive index difference is generated near the active region. This can be implemented by etching a ridge/mesa structure to the semiconductor after epitaxial growth (for example, in Ridge Waveguide (RWG) laser), or it can be done as a part of the epitaxial growth, in which case the ridge is surrounded by other semiconductor material. For best operating properties, sides of the ridge have to be covered with insulating material to ensure proper gain-guiding with current, i.e. only top of the ridge has to be uninsulated. This is usually done by depositing the insulating layer on the whole wafer, then doing photolithographic steps for etching the top of the ridge open. This, in turn, is achieved by leaving stripe with width of the ridge or less exposed to etching, and everything else being covered by photoresist, protecting the region where insulation is needed. After this step, metal is deposited on top of the ridges. Since only the top of the ridge is opened, when the current is driven to the device, the current goes through the semiconductor structure only through the ridge.

In the fabrication of mesa-type and similar semiconductor devices, one of the main problems is that of making an electrical contact to the mesa or other protuberance, which is usually very small and protrudes only a few micrometres above the relatively larger area of a surface of the remainder of the semiconductor body. For instance, when fabricating single-mode RWG lasers, ridge width has to be narrow (˜1-3 μm (micrometer), depending on operating wavelength) to ensure the single-mode operation. Due to the narrow widths of the ridge, alignment tolerances are really low. Further, existing semiconductor fabrication techniques are not self-aligning and alignment lithography is required to ease the strict alignments, or prevent misalignment of the open mask for further preventing non-symmetric opening of the ridge in which the insulating material covers the ridge partly from one side and exposes ridge side too much from the other side causing current leakage, electrical losses and distortion in the optical field output. Furthermore, insulating material residuals on top of the ridge may cause mechanical issues in cleaving due to the height difference on top of the ridge and also cause non-continuity to of the contact surface on top and reducing the efficiency of operation or yield losses in laser diode processes.

Traditionally, existing semiconductor fabrication employ wet etching of the insulating material or layer and/or planarization with benzo-cyclobutene (BCB). Such wet etching process removes the insulating material from the whole ridge; however, the wet etching process tends to also remove the insulating material from the sides of the ridge resulting in poor device properties. Further, the planarization with BCB causes nonuniform thicknesses throughout the layer due to spinning of the semiconductor substrate making the etching process of the planarization etching quite difficult. Furthermore, normal or conventional photolithography forming metal contacts to small-sized semiconductor devices, for example, a semiconductor device having a mesa or ridge dimension less than 1 micron reaches its limitation at this range.

Therefore, in light of the foregoing discussion, there exists a need to overcome the aforementioned drawbacks associated with existing fabrication techniques and provide an improved method for fabricating semiconductor devices.

### SUMMARY

The present disclosure seeks to provide a method for forming a contact surface on a top of a mesa structure formed on a semiconductor substrate. An aim of the present disclosure is to provide a solution that overcomes at least partially the problems encountered in prior art.

In one aspect, an embodiment of the present disclosure provides a method for forming a contact surface on a top of a mesa structure formed on a semiconductor substrate, wherein the semiconductor substrate is deposited with an insulating layer covering at least the top and side of the mesa structure, the method comprising:

depositing a first resist layer, of first resist material with first resist properties, over the insulating layer;

depositing a second resist layer, of second resist material with second resist properties, over the first resist layer, wherein the second resist properties of the second resist material are different than the first resist properties of the first resist material;

defining a first portion of the second resist layer, wherein the first portion overlaps the top of the mesa structure, and wherein at least one dimension of the first portion is greater than a corresponding at least one dimension of the top of the mesa structure;

forming a first opening in the first portion, by treating the second resist layer using a first treatment process responsive to the second resist material, wherein the first opening exposes a second portion of the first resist layer beneath thereof;

forming a second opening in the first resist layer, by treating the exposed second portion using a second treatment process responsive to the first resist material, wherein the second opening exposes a third portion of the insulating layer beneath thereof; and

etching the exposed third portion to form the contact surface on the top of the mesa structure.

In another aspect, an embodiment of the present disclosure provides a semiconductor device having a contact on a top of a mesa structure.

Embodiments of the present disclosure substantially eliminate or at least partially address the aforementioned problems in the prior art and provide an improved method for forming a contact surface on a top of a mesa structure formed on a semiconductor substrate, in which the semiconductor substrate is deposited with an insulating layer covering at least the top and sides of the mesa structure.

Additional aspects, advantages, features and objects of the present disclosure would be made apparent from the drawings and the detailed description of the illustrative embodiments construed in conjunction with the appended claims that follow.

It will be appreciated that features of the present disclosure are susceptible to being combined in various combinations without departing from the scope of the present disclosure as defined by the appended claims.

### BRIEF DESCRIPTION OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the present disclosure is not limited to specific methods and instrumentalities disclosed herein. Moreover, those skilled in the art will understand that the drawings are not to scale. Wherever possible, like elements have been indicated by identical numbers.

Embodiments of the present disclosure will now be described, by way of example only, with reference to the following diagrams wherein:

FIG. 1 is a flowchart listing steps involved in a method for forming a contact surface on a top of a mesa structure formed on a semiconductor substrate, in accordance with an embodiment of the present disclosure;

FIGS. 2A-2H are schematic cross-sectional illustrations of various stages involved in forming a contact surface on a top of a mesa structure formed on a semiconductor substrate, in accordance with various embodiments of the present disclosure;

FIGS. 3A-3H are schematic planar top view illustrations of various stages involved in forming a contact surface on a top of a mesa structure formed on a semiconductor substrate, in accordance with various embodiments of the present disclosure;

FIGS. 4A and 4B are schematic cross-sectional illustrations of one of various stages involved in forming a contact surface on a top of a mesa structure formed on a semiconductor substrate, in accordance with an embodiment of the present disclosure;

FIGS. 5A and 5B are schematic cross-sectional illustrations of the said one of various stages involved in forming a contact surface on a top of a mesa structure formed on a semiconductor substrate, in accordance with another embodiment of the present disclosure;

FIG. 6 is a SEM image taken from a processed semiconductor in which processing errors of conventional method are visible;

FIG. 7 is an example image of a semiconductor processed according to embodiments of the present disclosure and

FIG. 8 is an example image of a semiconductor processed according to embodiments of the present disclosure.

In the accompanying drawings, an underlined number is employed to represent an item over which the underlined number is positioned or an item to which the underlined number is adjacent. A non-underlined number relates to an item identified by a line linking the non-underlined number to the item. When a number is non-underlined and accompanied by an associated arrow, the non-underlined number is used to identify a general item at which the arrow is pointing.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practising the present disclosure are also possible.

In an aspect, an embodiment of the present disclosure provides a method for forming a contact surface on a top of a mesa structure formed on a semiconductor substrate, wherein the semiconductor substrate is deposited with an insulating layer covering at least the top and side of the mesa structure, the method comprising:

depositing a first resist layer, of first resist material with first resist properties, over the insulating layer;

depositing a second resist layer, of second resist material with second resist properties, over the first resist layer, wherein the second resist properties of the second resist material are different than the first resist properties of the first resist material;

defining a first portion of the second resist layer, wherein the first portion overlaps the top of the mesa structure, and wherein at least one dimension of the first portion is greater than a corresponding at least one dimension of the top of the mesa structure;

forming a first opening in the first portion, by treating the second resist layer using a first treatment process responsive to the second resist material, wherein the first opening exposes a second portion of the first resist layer beneath thereof;

forming a second opening in the first resist layer, by treating the exposed second portion using a second treatment process responsive to the first resist material, wherein the second opening exposes a third portion of the insulating layer beneath thereof; and

etching the exposed third portion to form the contact surface on the top of the mesa structure.

In another aspect, the present disclosure provides a semiconductor device having a contact on a top of a mesa structure, wherein a contact surface between a semiconductor substrate and the contact is formed using the method for forming a contact surface on a top of a mesa structure formed on a semiconductor substrate.

The present disclosure provides a method for forming a contact surface on a top of a mesa structure formed on a semiconductor substrate. Herein, the term “semiconductor substrate” refers to a layer or block of a material upon or within which elements of a semiconductor device are fabricated or attached. For example, the semiconductor substrate may be formed using at least one of silicon (Si), gallium (Ga), germanium (Ge), arsenic (As) and elements such as, nitrogen (N), carbon (C) and so forth or a combination of two or more of these materials such as, but not limited to, silicon carbide (SiC), gallium nitride (GaN), gallium arsenide (GaAs) or sapphire. Notably, the semiconductor substrate may be a layer of any metallic, non-metallic, semiconductor material or a combination of the metallic, non-metallic and semiconductor material, a layer of any material deposited on a supporting structure or the supporting structure itself. In present examples, the semiconductor substrate may be GaAs or InP based substrate which is suitable for forming HEMT and MESFET structures. However, the semiconductor substrate may be formed of any material on which it is desired to produce a sub-half micron pattern in accordance with the present disclosure. The semiconductor substrate may be formed using a variety of conventional techniques depending on the semiconductor device, integrated circuit or electronic structure to be formed, including such techniques as molecular beam epitaxy or metal-organic chemical vapor deposition. The particular construction of the substrates used in connection with the practice of the disclosed embodiments will not be further described since its application in connection with the present disclosure will be understood by those skilled in the art.

Further, the term “mesa structure” or “mesa” (also, sometimes, referred to as “ridge”) relates to the position or configuration (such as a ridge-like structure) of a structure on the semiconductor substrate having at least a top and one side, in which the top of the mesa structure is at an elevated level with respect to the mesa. In case of ridge the mesa structure has two elongated sides. A mesa structure might have also three of four sides. The term “contact surface” refers to a metal junction formed on the top of the mesa structure. Generally, the contact surface is formed using a semiconductor and/or metallic material and comprises a low electrical resistance. The contact surface is formed based on the implementation and selected from at least one of ohmic contact, Schottky contact, tunnel contact, annealed and/or alloyed contact. In an example, the semiconductor substrate is etched back to leave the semiconductor device (such as a transistor) isolated from surrounding material to prevent formation of parasitic capacitance arising from electrical carriers travelling via the contact surface.

In the present method for forming the contact surface on the top of the mesa structure, the semiconductor substrate is deposited with an insulating layer covering at least the top and sides of the mesa structure. Herein, the “insulating layer” refers to the dielectric material layer deposited over the mesa structure. Typically, the insulating layer refers to a dielectric electrical insulator configured to be polarized on application of an electric field (via the semiconductor device). Upon formation of the mesa structure on the semiconductor substrate i.e. once the ridges have been etched to the semiconductor material, the insulating layer may be deposited covering at least the top and sides of the mesa structure. Generally, the insulating layer covers the entire semiconductor substrate (and not just the top and sides of the mesa structure) without any limitations. Such process of depositing the insulating layer may be part of the present method of forming the contact surface (as described in detail later in the description), or a semiconductor substrate with a mesa structure and which comes pre-deposited with the insulating layer covering at least the top and the sides of the mesa structure may be utilized. The material for the insulating layer may be selected from at least one of porcelain or other ceramics, mica, glass, plastics, polymers and oxides of various metals and semiconductors. In an example, the insulating layer of silicon di-oxide (SiO₂) is deposited with a thickness of 300 nm. However, it will be appreciated that other suitable materials may be applied with different thickness without limiting the scope of the disclosure.

The present method comprises depositing a first resist layer, of first resist material with first resist properties, over the insulating layer. The method further comprises depositing a second resist layer, of second resist material with second resist properties, over the first resist layer, wherein the second resist properties of the second resist material are different than the first resist properties of the first resist material. That is, in embodiments of the present disclosure, upon depositing the first resist layer on the insulating layer, the second resist layer having second resist properties is deposited over the first resist layer. Notably, the second resist properties of the second resist material are different from the first resist properties of the first resist material. Optionally, the second resist properties of the second resist material may have some similar characteristics to the first resist properties of the first resist material; however, herein, the deposited first and second resist layers are selected such that pre- or post-treatment of the deposited first and second resist layers may allow the resist layers to be controllably dissolved or not dissolved as per requirement. Technical effect of that the properties are different is that a first treatment process can be selected to by such that it does not remove the first resist, when the first opening exposes a second portion of the first resist layer beneath thereof.

Herein, the term “resist layer” refers to a thin layer applied or deposited to define a pattern on the semiconductor substrate deposited upon. The resist layer may refer to a temporary mask configured to protect selected areas of the underlying semiconductor substrate. Generally, the material of the resist layer is a viscous solution of mixtures of one or more polymers and other small molecules. As used herein, the term “resist layer” is to include layer of liquid photopolymers which, after solidification, allow a high-fidelity transfer into a substrate by etching, however is not limited to photosensitive polymers only.

In an embodiment, depositing the first resist layer comprises spinning a layer of the first resist material over the insulating layer, heating the spun layer of the first resist material thereafter. The term “spinning” refers to a treatment technique or process implemented to deposit a material of uniform thickness over semiconductor substrates. Generally, a small amount of resist layer material is applied on the centre of a semiconductor substrate and rotated (or spun) at a speed of up to 10,000 rpm. In an example, the first resist layer is formed or deposited via spinning a photoresist material such as, AZ nLOF 2020, a negative resist having a high softening point and thermal stability, on the semiconductor substrate. Upon deposition of the first resist layer over the insulating layer, the first resist layer is treated using a treatment technique such as, but not limited to, heating or baking of the first resist layer, to solidify the first resist layer over the semiconductor substrate. Furthermore the depositing the first resist layer can also comprise exposing the first resist material to ultra-violet light.

In an embodiment, depositing the second resist layer comprises spinning a layer of the second resist material over the first resist layer, and heating the spun layer of the second resist material thereafter. The second resist layer is formed or deposited over the first resist layer using a photoresist material such as, but not limited to, a positive resist AZ 1514H. Upon depositing via spinning the second resist layer over the first resist layer on the semiconductor substrate, the second resist layer is then treated via heating or pre-baking the spun layer of the second resist material in a hotplate as per requirement, to solidify the second resist layer over the solidified first resist layer.

As discussed, the first and second resist layers have different resist properties that may beneficially be employed during further operation. The first resist layer formed using the first resist material comprises of first resist properties corresponding to the first resist material, and the second resist layer formed using the second resist material comprises of second resist properties corresponding to the second resist material. Herein, the “resist properties” refer to a set of properties that are measurable and whose value describes a state of the resist layer or material i.e. the physical, chemical and optical properties of the resist material or layer. Herein, the first resist properties refer to the set of properties associated to the first resist layer or material. The resist properties include, but is not limited to, melting point, boiling point, softening point, resolution i.e. the ability to differ the neighbouring features or elements on the semiconductor substrate, critical dimension (CD) i.e. a measure of resolution inversely proportional to the resolution, contrast i.e. the difference of the exposed portion to unexposed portion or covered portion to uncovered portion, sensitivity i.e. the minimum energy required to generate a well-defined feature on the resist layer on the semiconductor substrate, viscosity, adherence i.e. the adhesive strength between photoresist and semiconductor substrate, anti-etching ability i.e. ability of a photoresist to resist high temperatures, different pH environments and so forth, surface tension.

In an example, the first resist layer is a photoresist layer formed using a photolithography process on the semiconductor substrate. Upon deposition of the first resist layer on the insulating layer, the resist layer may be treated using various treatment techniques. Typically, the treatment of the first resist layer is implemented to enhance the first resist properties of the first layer by provide resistance during further development or operation. In an example, the second resist layer is also a photoresist layer formed, and similar process steps may be implemented for the second resist layer without any limitations.

Herein, the term “photoresist” refers to a type of photosensitive polymer that undergoes a photo exposure reaction when being exposed to light of a specific wavelength band. The photoresist may be a photo-polymeric photoresist, a photo-decomposing photoresist, or a photo-crosslinking photoresist. The term “exposure reaction” refers to the polymer chains of an exposed portion of the photoresist being broken or further bonded when exposed to light. In general, a photoresist is classified into a positive photoresist in which a polymer bonding chain of an exposed portion is broken and a negative photoresist in which a polymer bonding chain of an unexposed portion remains broken. That is, the positive photoresist has its exposure region developed through a subsequent development process, so a pattern of a non-exposure region remains. The negative photoresist has its non-exposure region developed, so a pattern of an exposure region remains.

In the present embodiments, the first resist material for the first resist layer is selected depending upon the nature of other resist layer materials to be applied during further operation. In an embodiment, the method comprises selecting the first resist material from one of: a negative photoresist material and a non-photoresist material, when the second resist layer is a positive photoresist layer. In another embodiment, the method comprises selecting the first resist material from one of: a positive photoresist material, image reversal photoresist material and a non-photoresist material, when the second resist layer is a negative photoresist layer. Herein, the “positive photoresist” refers to a type of photoresist, wherein the portion of the photoresist that is exposed to light or not covered by a mask, becomes soluble to a photoresist developer whereas the unexposed portion or the portion of the photoresist covered by the mask remains insoluble to the photoresist developer. Typically, the material used to form the positive photoresist is known as the positive photoresist material. In an example, the positive photoresist is a diazonaphthoquinone (DNQ)-novolac formed using combination of photoresist materials DNQ and novolac, in which the positive photoresist material is configured to be developed by dissolution in a basic solution of tetramethylammonium hydroxide (TMAH) in water. The “negative photoresist” refers to another type of photoresist, wherein the portion of the photoresist that is exposed to light becomes insoluble to the photoresist developer and the unexposed portion of the photoresist becomes soluble or dissolved by the photoresist developer. In an example, the negative photoresist may be an epoxy-based polymer or an off-stoichiometry thiol-enes (OSTE) polymer. Indeed, according to an alternative embodiment, if the first resist layer is negative photoresist the first resist layer then the first resist layer is exposed to light (such as ultra violet light) before the second resist is deposited. The “image reversal photoresist material” refers to photoresist material which can be treated either positive or negative way depending on the processing steps. For example, the image reversal photoresist is a DNQ-novolac. With a subsequent baking step after exposure to UV radiation, image reversal photoresist can be exposed with flood exposure (exposure without a photomask) when the earlier not-exposed parts of the photoresist are made soluble to developers. The “non-photoresist” refers to a type of material that is non-reactive to exposure unlike the photoresist material and may be employed to cover a defined pattern or portion of the photoresist layer to beneficially dissolve the uncovered or exposed portion of the photoresist.

According to embodiments of the present disclosure, upon depositing the second resist layer over the first resist layer, the second resist layer is exposed to a desired pattern and then developed for further operation. Beneficially, employing a bi-layer resist i.e. the first resist layer and the second resist layer, the bottom resist i.e. the first resist layer protects the sides of the ridge or mesa structure, such that any excess open or exposed area of the ridge sides does not cause losses in the semiconductor device. Optionally, instead of bi-layer resists, a single resist layer by replacing the first resist layer with other possible chemicals may be interchangeably employed without limiting the scope of the disclosure.

The method comprises defining a first portion of the second resist layer, wherein the first portion overlaps the top of the mesa structure, and wherein at least one dimension of the first portion is greater than a corresponding at least one dimension of the top of the mesa structure. That is, upon depositing the second resist layer, the method comprises defining the first portion on the second resist layer, wherein the first overlaps the top of the mesa structure. The “first portion” refers to a pattern or cross-section, overlapping or being directly over the top of the mesa structure. Beneficially, the first portion is made to overlap with the top of the mesa structure to achieve self-alignment in the semiconductor device. Herein, the at least one dimension of the first portion is greater than the at least one dimension of the top of the mesa structure. The “at least one dimension” may refer to a width, length, diagonal or radius of the top of the mesa structure, and, consequently, the first portion defined in the second resist layer. For example, in case of the top of the mesa structure having a circular shape, the at least one dimension for the first portion is the radius of a corresponding circular shaped first portion defined in the second resist layer. Typically, herein, the first portion is defined such that an area of the first portion is greater than an area of the top of the mesa structure, so that the first portion completely overlaps the top of the mesa structure. Thus, beneficially to avoid errors, the first portion covers a larger region than the top of the mesa structure, as discussed later in the description.

In an embodiment, the at least one dimension of the first portion is at least 2 times compared to the corresponding at least one dimension of the top of the mesa structure. Such extra 100 percent of difference in the at least one dimension of the first portion compared to the corresponding at least one dimension of the top of the mesa structure ensures that the first portion, generally, always covers an area or region greater than the top of the mesa structure due to the corresponding difference in the at least one dimension. In present embodiments, the at least one dimension of the first portion may vary from 2.0, 2.2, 2.4, 2.6, 2.8, 3.0, 3.2, 3.4, 3.6, 3.8, 4.0, 4.2, 4.4, 4.6, 4.8, 5.0, 6.0 times to 2.6, 2.8, 3.0, 3.2, 3.4, 3.6, 3.8, 4.0, 4.2, 4.4, 4.6, 4.8, 5.0, 6.0, 7.0, 10 times compared to the corresponding at least one dimension of the top of the mesa structure. The technical effect of this is that defining a first portion (for example during a lithography process), required tolerances of aligning for example a mask is reduced. As an example if the mesa is in a form of elongated ridge with width of 2 μm (micro meters) and length of 500 μm (micro meters). In conventional way the mask has to be aligned almost perfectly in top of the ridge. If the defined first portion is of width 8 μm and length of 500 μm then we have tolerance of 6 μm for miss alignment in respect to width making the process less critical to alignment errors. The portion can be thus aligned sidewise+−6 μm or it can be aligned in an angle in respect to the ridge of almost 0.7 degrees (arcsin(6/500)=0.68) giving additional benefit during the manufacturing process. As an comparison in a conventional method required tolerances for similar size mesa structure as in above example are less than 0.1 μm in sidewise direction. The angle between the elongated length of the ridge and used mask in the conventional manufacturing process can not deviate more than arcsin(0.1/500)=0.01 degrees in present example.

The method further comprises forming a first opening in the first portion, by treating the second resist layer using a first treatment process responsive to the second resist material, wherein the first opening exposes a second portion of the first resist layer beneath thereof. That is, upon defining the first portion on the second resist layer, the method comprises forming the first opening in the first portion. The term “first opening” refers to an open or uncovered volume in the second resist layer. The “treatment process” refers to a type of technique or procedure employed to remove the second resist material corresponding to the defined first portion from the second resist layer.

Herein, the first treatment process is applied or implemented in the second resist layer to define the first opening by removing the uncovered or exposed second resist material therein. For example, the first treatment process is an ultra-violet (UV) radiation technique. The term “UV radiation” is to be understood in principle as meaning all electromagnetic radiation which adjoins the short-wave part of the visible light, as a rule with a wavelength of less than 380 nm. This UV light is preferably so-called Medium-wave UV (UV-B) with wavelengths between about 280 nm to about 315 nm and short-wave UV (UV-C) with wavelengths of from 100, 120, 140, 160, 180, 200 nm up to 140, 160, 180, 200, 220, 240, 260 280 nm.

The first treatment process is implemented via an open mask pattern, as defined by the defined first portion. Beneficially, based on the implementation, the parameters of the treatment process such as the voltage, power, temperature, frequency, intensity and so forth may be varied to be suitable for and/or according to the second resist layer or material. Notably, the treated area defined by the first portion is wider or greater than the top of the mesa structure underneath, while the first resist layer remains deposited on the top of the mesa structure. In an example, the second photoresist material is dissolved via the developer is determined by the UV exposure, wherein the second resist material is either removed or not removed based on the type of photoresist employed.

The method further comprises forming a second opening in the first resist layer, by treating the exposed second portion using a second treatment process responsive to the first resist material, wherein the second opening exposes a third portion of the insulating layer beneath thereof. Upon, forming the first opening on the second resist layer to expose the first resist layer, the exposed or uncovered second portion of the first resist layer is treated using the second treatment process to remove the exposed first resist layer upon treatment through the second opening. For example, the second treatment process is an etching process, such as plasma etching configured to remove the exposed first resist material or layer to expose the layer beneath. Beneficially, the second treatment process removes the exposed first resist material to further expose the third portion on the insulating layer beneath thereof for further operation.

In an embodiment, the second resist layer is a positive photoresist layer, and wherein defining the first portion comprises masking portions of the positive photoresist layer other than the first portion, and wherein treating the second resist layer using the first treatment process comprises exposing the first portion to ultra-violet light, and developing the positive photoresist layer to remove the exposed first portion to expose the second portion. Herein, when the second resist layer is the positive photoresist layer, the first portion is defined by masking the region not encompassed by the first portion using a mask. Herein, the term “mask” or “photomask” refers to an opaque plate having holes or transparencies formed therein to allow exposure in a defined pattern. Notably, the pattern for the mask is defined by (or complementary to) the first portion, such that the mask covers the second resist layer other than the defined first portion therein. Herein, treating the second resist layer using the first treatment process comprises using UV light. Based on the pattern of the mask, the first portion is exposed with the UV light. The exposure to the UV light activates the photoactive compound in the exposed region (i.e. first portion) of the positive photoresist layer and makes it soluble to photoresist developers. Further, treating the second resist layer using the first treatment process comprises developing the positive photoresist layer. As discussed, in an example, the positive photoresist is a diazonaphthoquinone (DNQ)-novolac formed using combination of photoresist materials DNQ and novolac, in which the positive photoresist material is configured to be developed by dissolution in a basic solution of tetramethylammonium hydroxide (TMAH) in water. This removes the volume beneath the exposed first portion up to its thickness to form the first opening, and thereby exposing the second portion.

In another embodiment, the second resist layer is a negative photoresist layer, and wherein defining the first portion comprises masking the first portion of the second resist layer, and wherein treating the second resist layer using the first treatment process comprises exposing portions of the negative photoresist layer other than the first portion to ultra-violet light, and developing the negative photoresist layer to remove the unexposed portion of the negative photoresist layer to expose the second portion. Herein, when the second resist layer is the negative photoresist layer, the first portion is defined by masking the region encompassed by the first portion using a mask. Notably, the pattern for the mask is defined by (or complementary to) the first portion, such that the mask covers the defined first portion of the second resist layer. Herein, treating the second resist layer using the first treatment process comprises using UV light. Based on the pattern of the mask, the portion other than the first portion is exposed with the UV light. The exposure to the UV light activates the photoactive compound in the exposed region (i.e. portions other than the first portion) of the negative photoresist layer and makes it soluble to photoresist developers. Notably, in case of negative photoresist layer, the unexposed regions of the resist layer are dissolved by the developer. Further, treating the second resist layer using the first treatment process comprises developing the negative photoresist layer. This removes the volume beneath the unexposed first portion of the negative photoresist layer up to its thickness to form the first opening, and thereby exposing the second portion.

In an embodiment, treating the exposed second portion using the second treatment process comprises a plasma etching of the second portion. Herein, the second treatment process involves plasma etching which is be also referred as dry etching. etching. The second treatment process or the plasma etching treatment process enables controlling the plasma quality over the semiconductor substrate via the equipment and eliminating or reducing the dependence of an operator.

Beneficially, the controlled plasma etching enables forming the second opening in the first resist layer, exposing the insulating layer on the top of the mesa structure without removing the resist or insulating layer present on the sides of the mesa structure. In an example embodiment, the overall thickness of the second resist layer is kept larger than the overall thickness of the first resist layer, since, as may be contemplated, some of the thickness of the second resist layer is also lost during the plasma etching of the first resist layer.

In another embodiment, the plasma etching is an oxygen plasma etching. That is, the second treatment process i.e the plasma etching treatment process involves oxygen plasma etching. In an example, the semiconductor substrate is treated or etched using oxygen plasma for a period of 15 minutes, such that the insulating layer on the top of the mesa structure under the first resist layer is exposed. Beneficially, the oxygen plasma enables in developing or removing the resist layer or material through the plasma etching process in a controlled manner, in which the etch rate may be defined and controlled precisely to ensure that only thickness up to the first resist layer is removed, without harming the insulating layer on the top of the mesa structure, under the first resist layer. In an example thickness of the first resist layer is in between 1.5 to 2.3 μm for example between 1.5, 1.6, 1.7, 1.8, 1.9, 2.0 to 1.7, 1.8, 1.9, 2.0, 2.2, 2.3 μm.

In an embodiment, the method further comprising regulating a parameters of the oxygen plasma etching to remove a first resist with speed within a range of 1 to 200 nm/sec. This can be achieved for example by setting 50 Watt RF power to plasma etching device. The value depends on the make and provider of the plasma etching device. According to an embodiment the removal speed of the first resist can be from 1, 1.5, 2.0, 2.5, 3.0, 3.5, 4.0, 4.5, 5.0, 10, 20, 30, 40, 50, 60, 70, 80, 90, 100, 110, 120 nm/sec up to 3.0, 3.5, 4.0, 4.5, 5.0, 6.0, 7.0, 10, 20, 30, 40, 50, 60, 70, 80, 90, 100, 110, 120, 130, 140, 150, 160, 170, 180, 190, 200 nm/sec. Indeed the parameters are used to regulate the speed of removal of the resit with oxygen plasma etching to ensure that only thickness up to the first resist layer is removed, without harming the insulating layer on the top of the mesa structure, under the first resist layer. As an example, using a parameter of 50 W RF power, a removal speed of 2 nm/sec was achieved. The second treatment process (of oxygen plasma etching) with said parameter thus forms a second opening in the first resist layer (of example thickness of 1.8 μm) in 1.8 μm/2 nm/sec=900 sec (15 minutes). Thus after 15 minutes of treatment the treatment can be stopped and the third portion of the insulating layer is exposed. Benefit of using oxygen plasma treatment to remove the first resist is that it can be accurately controlled (by turning the RF power off). Indeed when comparing development with a chemical (as used in the first treatment process example) the plasma treatment is in order of magnitude more controllable.

The ideal process window is claimed to be when etch rate of the resist is between ranges of 1-20 nm/s. Going to rates below 1 nm/s would increase the total etching time too much, which can lead to difficult resist removal after the resist is exposed to long plasma etching. Further more if a higher etch speed is required the etching rate could be set higher such as 20-90 nm/s etch rate. The higher etch speed might be beneficial for thicker resist layers, so that the etch time is not too long. When having etch rate of 100-200 nm/s, etch rate starts to be so high that etch times would be seconds instead of minutes. Typically, a plasma process takes 1-10 seconds to stabilize, including plasma ignition and gas flow stabilizations, so if etching time is close or less than 30 seconds, uniform process throughout the sample is really hard to achieve. Exceeding 200 nm/s makes the process control even harder, nearly impossible without having to compromise with yield issues. Indeed based on experiments if the removal speed is higher than 200 nm/sec then it is difficult to control the process and yield of the manufacturing process decreases. With said high removal speed resist of for example 2.0 μm would be removed in 10 seconds. This fast process would difficult to control since process setup and stabilisation of the process takes also time. Corresponding etching times for rates of 1-200 nm/sec can be calculated using thickness of the first resist to be removed. Term nm/sec can be also considered thus as a time range (seconds).

According to an embodiment the first treatment process responsive to the second resist is different from the second treatment process responsive to the first resist. This is beneficial as the first treatment process does not need to be as accurate as the second treatment process since the first treatment process does not remove the first resist. For this reason the first treatment process can be for example chemical based which might be faster and less expensive than etching process (the second treatment process).

The method further comprises etching the exposed third portion to form the contact surface on the top of the mesa structure. Upon forming the second opening in the first resist layer and exposing the third portion of the insulating layer which covers the top of the mesa structure, the third portion of the insulating layer is removed or etched to expose the top of the mesa structure, and thereby allows forming the contact surface on the top of the mesa structure. The techniques for forming the contact surface on the top of the mesa structure are well known and thus not described herein for the brevity of the present disclosure.

In an embodiment, the etching of the exposed third portion is a plasma etching. Optionally, the insulating layer is removed or etched from the top of the mesa structure using a third treatment process, wherein the third treatment process may or may not be similar to the first or second treatment processes. In an example, the third treatment process is oxygen plasma etching. In another example, the third treatment process is a reactive ion etching (RIE) process using CHF₃ and Ar plasma.

In an embodiment, the method further comprises restricting the first opening by the defined first portion, to have the first opening in the second resist layer in a shape of a frustum. Restricting the first opening by the defined first portion ensures that the first opening formed in the second resist layer would still be overlapping the top of the mesa structure. The frustum shape of the first opening tends to make the area of the exposed region closer to the area of the top of the mesa structure, and thus ensuring that the layers beneath thereof are further developed, the exposed region tends to be of the same area as the area of the top of the mesa structure.

Beneficially, using bi-layer resists, i.e. the first resist layer and the second resists layer, in contrast to conventional methods where only one resist layer is typically employed, in the present method as disclosed, no strict alignment is needed due to the underlaying resist protecting the ridge from the sides. This is achieved due to the second resist layer being exposed from an area wider than the top of the mesa structure. Thus, the first resist layer enables protection from the sides of the mesa structure to prevent excess opening which may otherwise cause various losses in a semiconductor device fabricated using such semiconductor substrate. That is, using bi-layer resist, the bottom resist will protect the sides of the ridge, so that excess open of the ridge sides does not cause losses in the semiconductor device.

In another aspect, the present disclosure provides a semiconductor device having a contact on a top of a mesa structure, wherein a contact surface between a semiconductor substrate and the contact is formed using the method for forming a contact surface on a top of a mesa structure formed on a semiconductor substrate. Typically, the semiconductor device is fabricated using the semiconductor substrate with the contact surface on the top of the mesa structure formed therein using the method of the present disclosure, and thereby achieves all features and advantages of the method. Herein, the “semiconductor device” refers to an electronic component comprising of a semiconductor material such as, but not limited to, silicon, germanium, and gallium arsenide, as well as organic semiconductors. Generally, the semiconductor devices are manufactured both as a single discrete device and as an integrated circuit (IC) chip consisting of two or more electronic devices and interconnected on a single semiconductor substrate. Examples of semiconductor devices include transistors, diodes, light-emitting diodes (LEDs), solar cells, laser diode and so forth.

In an embodiment, the semiconductor device is a laser. The “laser” or “semiconductor laser” refers to a device configured for laser oscillation by flowing an electric current to the semiconductor device through the contact surface. The mechanism of light emission is the same as a light-emitting diode (LED). Herein, the laser generates light by flowing the forward current such as, to a p-n junction. In an exemplary forward bias operation, the p-type layer is connected with the positive terminal and the n-type layer is connected with the negative terminal, such that the electrons enter from the n-type layer and holes from the p-type layer, respectively. Upon contact at the p-n at the junction, the semiconductor device or laser, an electron drops into a hole and correspondingly light is emitted at the contact surface.

Generally, the semiconductor is fabricated by depositing the insulating layer on the whole wafer and performing photolithographic steps for etching the top of the ridge open and leaving stripes with width of the ridge exposed to etching, and wherein the rest of the region is covered by a photoresist, to protect the part or portion where insulation is required. Generally, for single-mode RWG lasers, the width of the mesa structure or top of the mesa structure has to be narrow (˜1-3 μm, depending on operating wavelength) to ensure the single-mode operation. In embodiments of the present disclosure, since the sides of the ridge are covered with an insulating material, this ensures proper gain-guiding with current, i.e. only top of the ridge is required to be uninsulated. That is, since only the top of the ridge is opened, with the contact surface is present on the top of the mesa structure or semiconductor device, the current driven through the semiconductor structure passes only through the ridge, ensuring proper lasing in case of, for example, the semiconductor device being the laser.

Modifications to embodiments of the present disclosure described in the foregoing are possible without departing from the scope of the present disclosure as defined by the accompanying claims. Expressions such as “including”, “comprising”, “incorporating”, “have”, “is” used to describe and claim the present disclosure are intended to be construed in a non-exclusive manner, namely allowing for items, components or elements not explicitly described also to be present. Reference to the singular is also to be construed to relate to the plural.

### DETAILED DESCRIPTION OF THE DRAWINGS

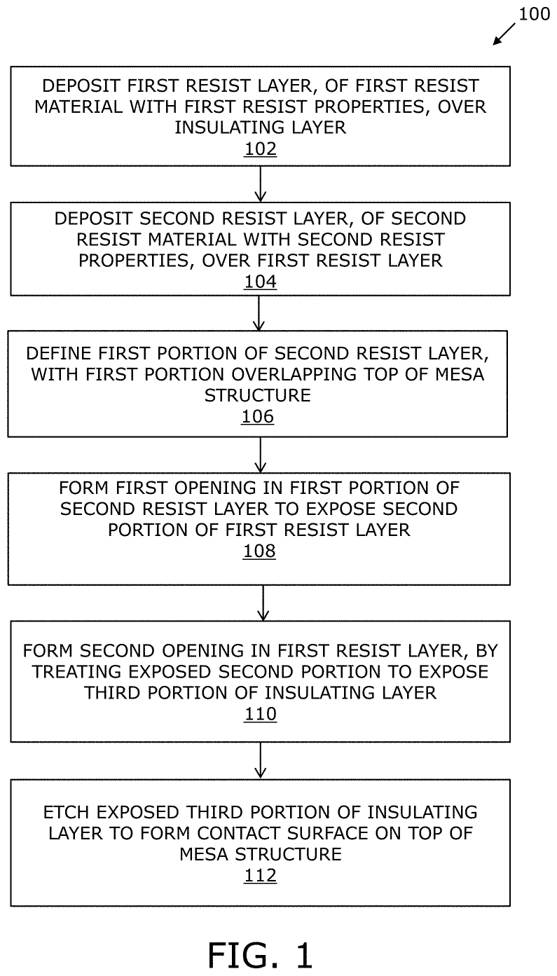

Referring to FIG. 1, illustrated is a flowchart of a method 100 for forming a contact surface on a top of a mesa structure formed on a semiconductor substrate, wherein the semiconductor substrate is deposited with an insulating layer covering at least the top and sides of the mesa structure. As shown, the method 100 comprises steps 102, 104, 106, 108, 110 and 112.

At step 102, the method 100 comprises depositing a first resist layer, of first resist material with first resist properties, over the insulating layer. Upon deposition of the insulating layer on the mesa structure, the method 100 comprises depositing the first resist layer over the insulating layer. Herein, depositing the first resist layer comprises spinning a layer of the first resist material over the insulating layer and heating the spun layer of the first resist material thereafter.

At step 104, the method 100 comprises depositing a second resist layer, of second resist material with second resist properties, over the first resist layer, wherein the second resist properties of the second resist material are different than the first resist properties of the first resist material. Upon deposition of the first resist layer over the insulating layer, the method 100 comprises depositing the second resist layer over the first resist layer. Herein, depositing the second resist layer comprises spinning a layer of the second resist material over the first resist layer, and heating the spun layer of the second resist material thereafter.

At step 106, the method 100 comprises defining a first portion of the second resist layer, wherein the first portion overlaps the top of the mesa structure, and wherein at least one dimension of the first portion is greater than a corresponding at least one dimension of the top of the mesa structure. The first portion is defined depending on the resist properties of the second resist layer. When the second resist layer is a positive photoresist layer, defining the first portion comprises masking portions of the positive photoresist layer other than the first portion. When the second resist layer is a negative photoresist layer, defining the first portion comprises masking the first portion of the second resist layer.

At step 108, the method 100 comprises forming a first opening in the first portion, by treating the second resist layer using a first treatment process responsive to the second resist material, wherein the first opening exposes a second portion of the first resist layer beneath thereof. That is, upon defining the first portion, the method 100 comprises forming the first opening of the second resist layer, by treating the second resist layer using the first treatment process to expose the second portion. Herein, when the second resist layer is a positive photoresist layer and the first portion is defined by masking portions of the positive photoresist layer other than the first portion, treating the second resist layer using the first treatment process comprises exposing the first portion to ultra-violet light, and developing the positive photoresist layer to remove the exposed first portion to expose the second portion. Alternatively, when the second resist layer is a negative photoresist layer and the first portion is defined by masking the first portion of the second resist layer, treating the second resist layer using the first treatment process comprises exposing portions of the negative photoresist layer other than the first portion to ultra-violet light, and developing the negative photoresist layer to remove the unexposed portion of the negative photoresist layer to expose the second portion.

At step 110, the method 100 comprises forming a second opening in the first resist layer, by treating the exposed second portion using a second treatment process responsive to the first resist material, wherein the second opening exposes a third portion of the insulating layer beneath thereof. That is, upon forming the first opening, the method 100 comprises forming the second opening by treating the exposed second portion using the second treatment process to expose the third portion of the insulating layer. Herein, treating the exposed second portion using the second treatment process comprises a plasma etching of the second portion. Herein, the plasma etching is an oxygen plasma etching.

At step 112, the method 100 comprises etching the exposed third portion to form the contact surface on the top of the mesa structure. That is, upon forming the second opening, the method 100 comprises etching the exposed third portion to form the contact surface on the top of the mesa structure. Notably, only the top of the mesa structure is etched, and the sides of the mesa structure are left insulated.

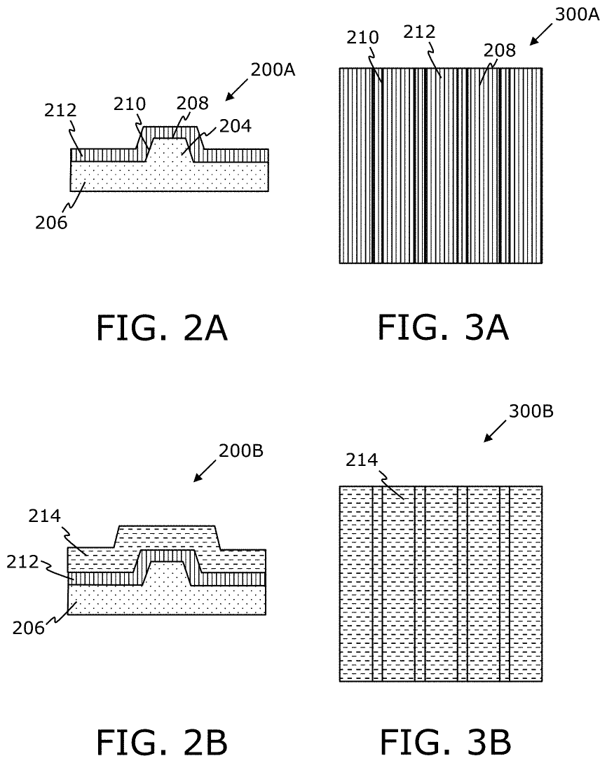

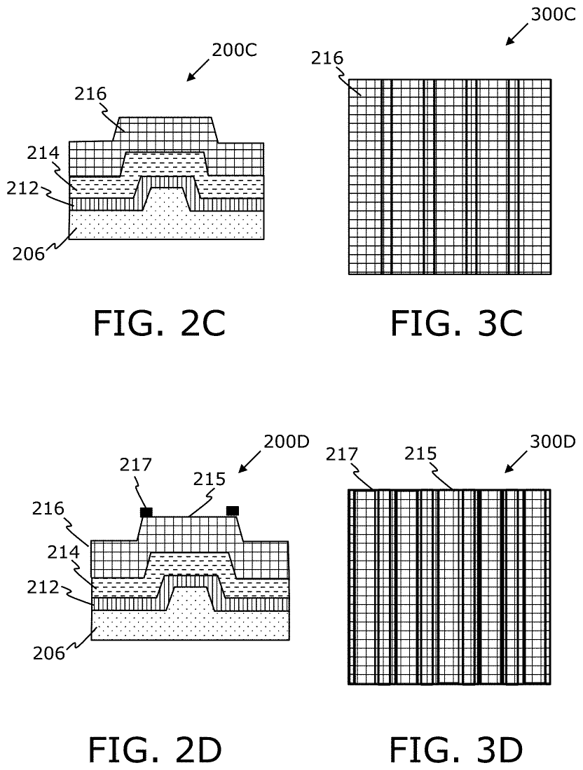

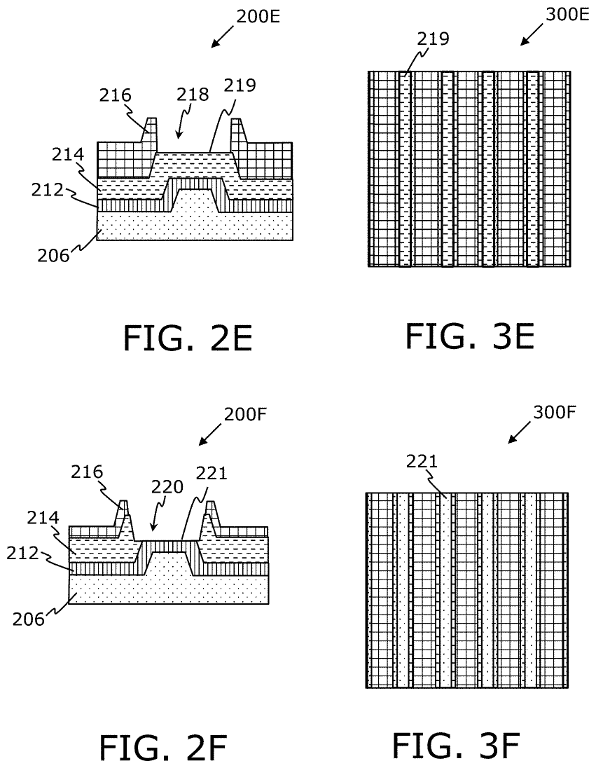

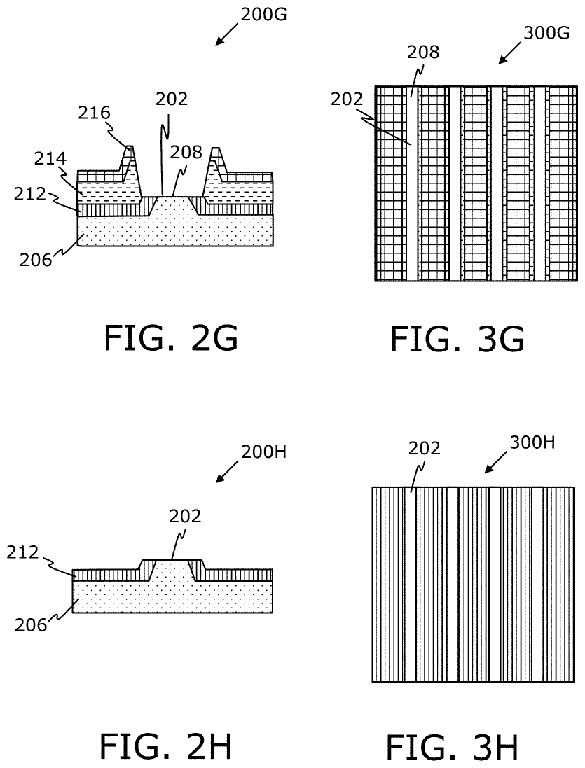

Referring to FIGS. 2A-2H, illustrated are schematic cross-sectional illustrations of various stages 200A-200H involved in forming a contact surface 202 on a top 208 of a mesa structure 204 formed on a semiconductor substrate 206, in accordance with an embodiment of the present disclosure. Referring to FIGS. 3A-3H, illustrated are schematic planar top view illustrations of various stages 300A-300H (corresponding to the stages 200A-200H) involved in forming the contact surface 202 on the top 208 of the mesa structure 204 formed on the semiconductor substrate 206, in accordance with an embodiment of the present disclosure. Notably, FIGS. 2A-2H and FIGS. 3A-3H are arranged and shown distinctly and should be read in conjunction or corresponding to each step of the method 100 of FIG. 1. For example, the step 102 of FIG. 1 corresponding to FIGS. 2A and 3A, the step 104 of FIG. 1 corresponding to FIGS. 2B and 3B, and so forth.

Referring to FIGS. 2A and 3A, in combination, at stage 200A, 300A, the semiconductor substrate 206 deposited with an insulating layer 212 covering at least the top 208 and sides 210 of the mesa structure 204 is provided.

Referring to FIGS. 2B and 3B, in combination, at stage 200B, 300B, a first resist layer 214 of first resist material with first resist properties is deposited over the insulating layer 212.

Referring to FIGS. 2C and 3C, in combination, at stage 200C, 300C, upon depositing the first resist layer 214 over the insulating layer 212, a second resist layer 216, of second resist material with second resist properties, is deposited over the first resist layer 214, wherein the second resist properties of the second resist material are different than the first resist properties of the first resist material.

Referring to FIGS. 2D and 3D, in combination, at stage 200D, 300D, upon depositing the second resist layer 216 over the first resist layer 214, a first portion 215 of the second resist layer 216 is defined by implementing a mask 217, wherein the first portion 215 overlaps the top 208 of the mesa structure 204.

Referring to FIGS. 2E and 3E, in combination, at stage 200E, 300E, upon defining the first portion 215, a first opening 218 is formed in the first portion 215 of the second resist layer 216, by treating the second resist layer 216 using a first treatment process responsive to the second resist material, wherein the first opening 218 exposes a second portion 219 of the first resist layer 214 beneath thereof.

Referring to FIGS. 2F and 3F, in combination, at stage 200F, 300F, upon forming the first opening 218, a second opening 220 is formed in the first resist layer 214, by treating the exposed second portion 219 of the first resist layer 214 using a second treatment process responsive to the first resist material, wherein the second opening 220 exposes a third portion 221 of the insulating layer 212 beneath thereof.

Referring to FIGS. 2G and 3G, in combination, at stage 200G, 300G, upon forming the second opening 220 and exposing the third portion 221 of the first resist layer 214, the exposed third portion 221 of the insulating layer 212 is etched to form the contact surface 202 on the top of the mesa structure 204. Notably, only the top 208 of the mesa structure 204 is etched, and the sides 210 of the mesa structure 204 are left insulated.

Referring to FIGS. 2H and 3H, in combination, at stage 200H, 300H, upon etching the exposed third portion 221 of the insulating layer 212, the first and second resist layers 214, 216 are stripped or removed using any one of a treatment technique or chemical developers to form the contact surface 202 on the top 208 of the mesa structure 204.

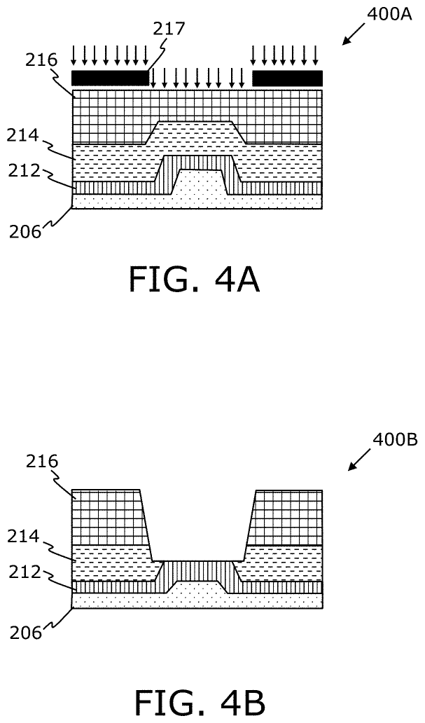

Referring to FIGS. 4A and 4B, illustrated are schematic cross-sectional illustrations of stages 400A, 400B in a process for implementing the stage 200E, 300E, in accordance with an embodiment of the present disclosure. Herein, the second resist layer 216 is a positive photoresist layer. As shown in FIG. 4A, defining the first portion 215 of the second resist layer 216 comprises masking, using the mask 217, portions of the positive photoresist layer 216 other than the first portion 215 of the positive photoresist layer 216. As shown in FIG. 4B, treating the second resist layer 216 using the first treatment process comprises exposing the first portion 215 of the positive photoresist layer 216 to ultra-violet light, and developing the positive photoresist layer to remove the exposed first portion 215 of the positive photoresist layer 216 to further expose the second portion 219 of the first resist layer 214.

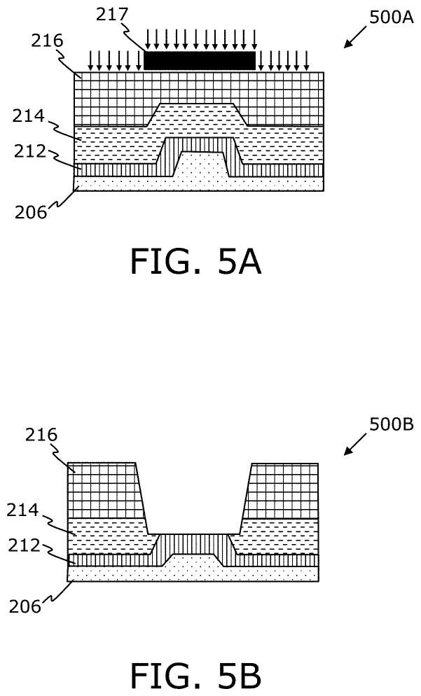

Referring to FIGS. 5A and 5B, illustrated are schematic cross-sectional illustrations of stages 500A, 500B in a process for implementing the stage 200E, 300E, in accordance with another embodiment of the present disclosure. Herein, the second resist layer 216 is a negative photoresist layer. As shown in FIG. 5A, defining the first portion 215 of the second resist layer 216 comprises masking, using the mask 217, the first portion 215 of the negative photoresist layer 216. As shown in FIG. 5B, treating the second resist layer 216 using the first treatment process comprises exposing the portions other than the first portion 215 of the negative photoresist layer 216 to ultra-violet light, and developing the negative photoresist layer to remove the unexposed first portion 215 of the negative photoresist layer 216 to further expose the second portion 219 of the first resist layer 214.

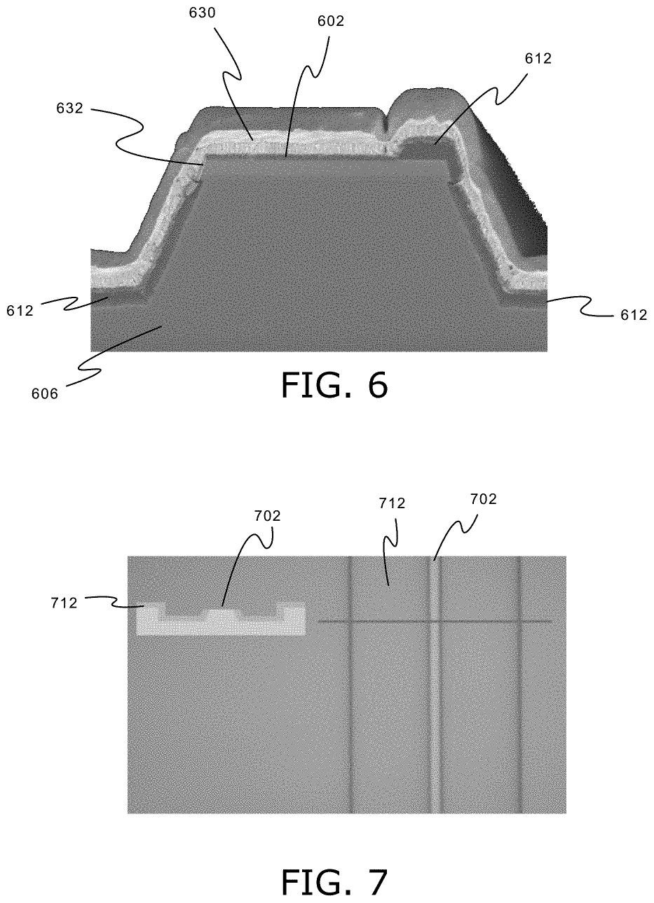

A FIG. 6. is a scanning electron microscope (SEM) image example of semiconductor in which a contact surface 602 has manufacturing defect. The FIG. 6. indeed is an illustration example of problem in conventional method when forming a contact surface 602 and a contact 630 in top of that. The semiconductor substrate 606 has partially overlaying insulating layer 612. The insulating layer 612 has been removed from a top of mesa structure as illustrated. After the removal a contact 630 has been deposited. The contact 630 can be for example aluminium that is grown in top of the semiconductor structure. As it can be seen that the contact 630 is in contact with the semiconductor substrate on areas in which the insulating layer has been removed (thus forming electrical connection for operate the semiconductor). The contact surface 602 is in the figure misaligned i.e. the contact 630 is in contact partially with a side of the mesa in section marked with 632. Further the miss-alignment has resulted that some of the insulating layer 612 is covering the top of the mesa. These defects might have a negative impact on operation of the semiconductor.

FIG. 7 is an optical microscope image taken from a semiconductor processed with the disclosed method. It can be seen that the contact surface 702 is aligned precisely with a top of an elongated mesa. Insulating layer 712 is thus removed from top of the mesa. The figure illustrates also cross section. It can be seen from the cross section that insulating layer 712 is removed correctly. Indeed using the disclosed self-alignment method a yield of semiconductor manufacturing in increased.

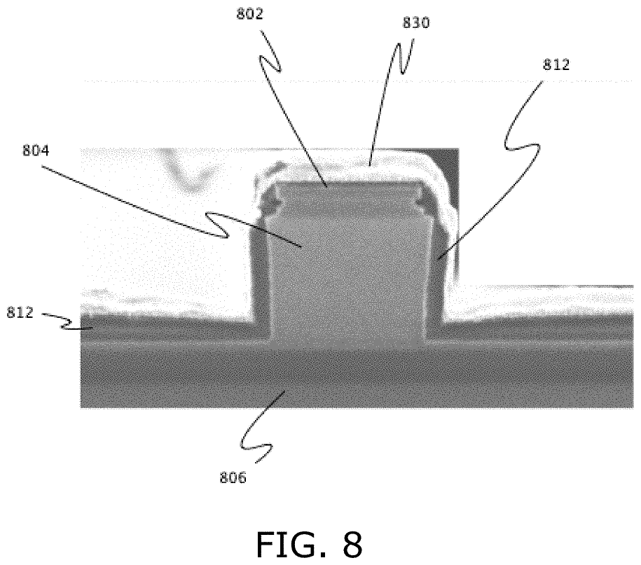

FIG. 8 is a scanning electron microscope image taken from a semiconductor manufactured using disclosed method. It can be seen that a contact surface 802 is perfectly aligned in top of a mesa structure 804 formed in top of the semiconductor substrate 806. An insulating layer 812 is on top of the substrate 806 and on the sides of the mesa 804. The insulating layer 812 is removed from the top of the mesa 804 thus forming electrically and optically good contact surface 802 thus improving operation of the semiconductor.

1. A method for forming a contact surface on a top of a mesa structure formed on a semiconductor substrate, wherein the semiconductor substrate is deposited with an insulating layer covering at least the top of the mesa structure and a side of the mesa structure, the method comprising:
depositing a first resist layer of a first resist material with first resist properties over the insulating layer;
depositing a second resist layer of a second resist material with second resist properties over the first resist layer, wherein the second resist properties of the second resist material are different from the first resist properties of the first resist material;
defining a first portion of the second resist layer, wherein the first portion overlaps the top of the mesa structure, and wherein at least one dimension of the first portion is greater than a corresponding at least one dimension of the top of the mesa structure;
forming a first opening in the first portion by treating the second resist layer using a first treatment process responsive to the second resist material, wherein the first opening exposes a second portion of the first resist layer;
forming a second opening in the first resist layer by treating the exposed second portion using a second treatment process responsive to the first resist material, wherein the second opening exposes a third portion of the insulating layer; and
etching the exposed third portion to form the contact surface on the top of the mesa structure.

2. The method according to claim 1, wherein depositing the first resist layer comprises spinning a layer of the first resist material over the insulating layer and heating the spun layer of the first resist material thereafter.

3. The method according to claim 1, wherein depositing the second resist layer comprises spinning a layer of the second resist material over the first resist layer, and heating the spun layer of the second resist material thereafter.

4. The method according to claim 1, wherein the second resist layer is a positive photoresist layer, and wherein defining the first portion comprises masking portions of the positive photoresist layer other than the first portion, and wherein treating the second resist layer using the first treatment process comprises exposing the first portion to ultra-violet light, and developing the positive photoresist layer to remove the exposed first portion to expose the second portion.

5. The method according to claim 1, wherein the second resist layer is a negative photoresist layer, and wherein defining the first portion comprises masking the first portion of the second resist layer, and wherein treating the second resist layer using the first treatment process comprises exposing portions of the negative photoresist layer other than the first portion to ultra-violet light, and developing the negative photoresist layer to remove the unexposed portion of the negative photoresist layer to expose the second portion.

6. The method according to claim 1 further comprising selecting the first resist material from one of a negative photoresist material and a non-photoresist material.

7. The method according to claim 1 further comprising selecting the first resist material from one of a positive photoresist material and a non-photoresist material.

8. The method according to claim 1, wherein treating the exposed second portion using the second treatment process comprises a plasma etching of the second portion.

9. The method according to claim 8, wherein the plasma etching is an oxygen plasma etching.

10. The method according to claim 9 further comprising regulating a parameters of the oxygen plasma etching to remove the first resist with speed within a range of 1 to 200 nm/sec.

11. The method according to claim 1, wherein the at least one dimension of the first portion is at least 2 times compared to the corresponding at least one dimension of the top of the mesa structure.

12. The method according to claim 1 further comprising restricting the first opening by the defined first portion, to have the first opening in the second resist layer in a shape of a frustum.

13. The method according to claim 1, wherein the etching of the exposed third portion is a plasma etching.

14. A semiconductor device having a contact on a top of a mesa structure, wherein a contact surface between a semiconductor substrate and the contact is formed using the method according to claim 1.

15. The semiconductor device according to claim 14, wherein the semiconductor device is a laser.
